(19) United States
(12) Patent Application Publication
(10) Pub. No.: US 2026/0350248 A1
(43) Pub. Date: Nov. 5, 2026

(54) INTERIOR COMMUNICATION ASSISTANCE SYSTEM AND INTERIOR COMMUNICATION ASSISTANCE PROGRAM

(71) Applicant: Sekisui House, Ltd., Osaka-Shi, Osaka (JP)

(72) Inventors: Takahiro Suezawa, Osaka-shi (JP); Naoko Yano, Osaka-shi (JP); Kazumi Maehara, Osaka-shi (JP); Nao Adachi, Osaka-shi (JP); Mizuki Doi, Osaka-shi (JP); Yukako Komoto, Osaka-shi (JP)

(73) Assignee: Sekisui House, Ltd., Osaka-Shi, Osaka (JP)

(21) Appl. No.: 19/485,404

(22) PCT Filed: Nov. 30, 2023
(86) PCT No.: PCT/JP2023/042985

§ 371 Date: Nov. 18, 2025

(30) Foreign Application Priority Data
May 30, 2023 (JP) 2023-088864

(51) Int. Cl. G06F 30/13; G06F 9/451

(52) U.S. Cl. CPC G06F 30/13; G06F 9/453

(57) ABSTRACT

An interior communication assistance system includes a controller and storage. The storage stores multiple images of at least an interior decor of a building. The controller includes a register, an obtainer, an information generator, and an output unit. The register is configured to register a person who uses the interior communication assistance system as a registered person and store information related to the registered person in the storage as registration information. The obtainer is configured, when the images and a question about the images are shown on a display, to obtain an answer to the question from the registered person as answer information. The information generator is configured to generate preference information in which preference of the registered person is organized based on the answer information. The output unit is configured to show the preference information on the display.

### TECHNICAL FIELD

The present disclosure relates to a building interior communication assistance system and a building interior communication assistance program.

### BACKGROUND ART

A system for assisting in planning the design of a building is known (for example, Patent Literature 1). The system disclosed in the Literature elicits a request from a customer effectively. The system in the Literature shows six to ten presentations of different orientation types, each of which indicates an interior orientation, in a matrix of two rows on paper or a screen.

### CITATION LIST

### Patent Literature

Patent Literature 1: JP2001-142924A

### SUMMARY OF INVENTION

### Technical Problem

Customer requests may be captured with such a system. However, customer requests related to design vary widely and thus are not easy to capture. Therefore, there is room for improvement in an interior communication assistance system and an interior communication assistance program.

### Solution to Problem

(1) To solve the above problem, an interior communication assistance system assists in design planning of a building. The interior communication assistance system includes a controller and storage. The storage stores multiple images of at least an interior decor of the building. The controller includes a register configured to register a person who uses the interior communication assistance system as a registered person and store information related to the registered person in the storage as registration information, an obtainer configured, when the images and a question about the images are shown on a display, to obtain an answer to the question from the registered person as answer information, an information generator configured to generate preference information in which preference of the registered person is organized based on the answer information, and an output unit configured to show the preference information on the display. This configuration assists the designer in accurately determining the preference of the registered person (e.g., customer).
(2) In the interior communication assistance system according to the above description (1), the images, each of which includes an image of an interior decor, differ from each other in interior feature. The question includes a first question that asks the registered person to select whether the images are preferred. When the images and the first question about the images are shown on the display, the obtainer obtains an answer to the first question from the registered person as first answer information. The information generator generates the preference information including the registration information and a better image selected as preferred in the first question. This configuration allows for determination of the design of the interior decor that is preferred by the registered person.
(3) In the interior communication assistance system according to the above description (2), the question includes a second question including at least one of a material-related question and a spatial configuration-related question, the material-related question asking the registered person to select whether a particular element of the interior decor in the images is preferred, and the spatial configuration-related question asking the registered person to select whether the interior decor in the images or a space in which the interior decor is represented is preferred. The obtainer obtains an answer to the second question about the better image, which is selected as preferred in the first question, as second answer information. The information generator generates the preference information in which the registration information is associated with the better image and the second answer information. This configuration allows for determination of the design of the interior decor preferred by the registered person or the interior space (space expressed by the interior decor) preferred by the registered person. Also, this configuration allows for determination of which part of the preferred interior decor is preferred.
(4) In the interior communication assistance system according to the above description (2), the question includes a second question including at least one of a material-related question and a spatial configuration-related question, the material-related question asking the registered person to select whether a particular element of the interior decor in the images is preferred, and the spatial configuration-related question asking the registered person to select whether the interior decor in the images or a space in which the interior decor is represented is preferred, and a third question asking the registered person to select a predetermined number of images from the better image, which is selected as preferred in the first question, as a best image. The best image is more preferred among the better image. The obtainer obtains an answer to the second question about the best image, which is selected as more preferred in the third question, as second answer information. The information generator generates the preference information in which the registration information is associated with the best image and the second answer information. This configuration allows for narrowing down of the design of the interior decor preferred by the registered person or the interior space (space expressed by the interior decor) preferred by the registered person. Also, this configuration allows for determination of which part of the preferred interior decor is preferred.
(5) In the interior communication assistance system according to the above description (3) or (4), the controller further includes a comment adding unit that adds a comment of the registered person to the preference information on the registered person. The comment adding unit adds a comment entered by the registered person on a question content that is positively answered in the second question to the preference information so that the comment is associated with the question content. This configuration allows for determination of the comment on the preferred part.
(6) In the interior communication assistance system according to any one of the above descriptions (3) to (5), the particular element includes a surface element that forms a surface of an interior decor and an item element related to an item forming the interior decor. The surface element includes at least one of a floor of the interior decor, a wall of the interior decor, and a ceiling of the interior decor. The item element includes at least one of lighting of the interior decor and an interior accessory forming the interior decor. The material-related question includes a question asking whether the surface element is preferred and a question asking whether the item element is preferred. This configuration allows for determination or inference of whether the surface element of the interior decor is preferred, whether the item element of the interior decor is preferred, whether both the surface element and the item element are preferred, or whether a combination of the surface element and the item element is preferred in the preferred interior decor.
(7) The interior communication assistance system according to any one of the above descriptions (1) to (6) further includes an information provider configured to provide information related to an element included in the image, in the images, each image is configured so that the element included in the image is associated with element information related to the element, and when the image is shown on the display, the information provider forms a link to the element information of the element included in the image on the display so that the element information of the element is shown when selected. With this configuration, detailed information about the building materials of the interior decor preferred by the registered person is obtained.
(8) In the interior communication assistance system according to the above description (7), the element information related to the element is configured to be associated with related element information that is in same type as the element. When the image is shown on the display, the information provider forms a link to the related element information on the display so that the related element information is shown when selected.

With this configuration, various building materials that may be close to the preference of the registered person may be proposed based on the interior decor preferred by the registered person.
(9) In the interior communication assistance system according to any one of the above descriptions (1) to (8), in the images, each image is configured to be associated with concept information describing concept of an interior decor related to the image, and further includes a concept information provider configured to provide a concept of an interior decor included in the image. When the image is shown on the display, the concept information provider forms a link to the concept information on the display so that the concept information is shown when selected. This configuration allows for determination of the concept of the interior decor that is preferred by the registered person.
(10) The interior communication assistance system according to any one of the above descriptions (1) to (9), further includes an information adding unit configured to add information to the preference information on the registered person. The information adding unit adds an additional image provided by the registered person to the preference information as a piece of the preference information on the registered person. With this configuration, the additional image allows for deep understanding of the preference of the registered person.
(11) The interior communication assistance system according to any one of the above descriptions (1) to (10) further includes an information manager configured to manage information obtained by the obtainer. The registered person includes multiple registered persons. The register registers the registered persons as members of a group in accordance with group setting. The information generator generates the preference information for each of the registered persons. The information manager allows an information terminal of the registered person who is a member in the group to access the preference information and restricts access to the preference information by an information terminal of the registered person outside the group so that the preference information is shared by only the members of the group. With this configuration, the preference of each member in the group is shared. For example, when all members in a family decide interior decor of the building, the members may share their preferences. Thus, the proposal of the interior decor is readily finalized.
(12) In the interior communication assistance system according to the above description (11), the register registers a person who operates the interior communication assistance system in accordance with operator setting. The information manager allows the operator to access the registered person information and the preference information. This configuration allows all of the registered operators to share the preference of the registered person. When the interior decor is designed by multiple operators, the operators can share the information to smoothly design the interior decor.
(13) To solve the above problem, an interior communication assistance program assists in design planning of a building. The interior communication assistance program includes a step of causing a computer to store multiple images of at least an interior decor of the building, a step of causing the computer to register a person who uses the interior communication assistance program as a registered person and store information related to the registered person in storage as registration information, a step of causing the computer, when the images and a question about the images are shown on a display, to obtain an answer to the question from the registered person as answer information, a step of causing the computer to generate preference information in which preference of the registered person is organized based on the answer information, and a step of causing the computer to show the preference information on the display. This configuration assists the designer in accurately determining the preference of the registered person (e.g., customer).

### Advantageous Effects of Invention

The interior communication assistance system and the interior communication assistance program according to the present disclosure assist a designer in accurately determining a preference of a customer.

### BRIEF DESCRIPTION OF DRAWINGS

FIG. 1 is a diagram showing a system including an interior communication assistance system.

FIG. 2 is a block diagram showing an interior communication assistance system.

FIG. 3 is a schematic diagram showing relationships between an image and different types of information.

FIG. 4 is a diagram of a display screen showing a first question.

FIG. 5 is a diagram of a display screen showing a list of better images.

FIG. 6 is a diagram of a display screen showing a third question.

FIG. 7 is a table showing specific examples of various questions in a second question.

FIG. 8 is a diagram of a display screen showing the second question.

FIG. 9 is a table showing preference information.

FIG. 10 is a diagram of a display screen showing an image associated with different types of information.

FIG. 11 is a diagram of a display screen showing a list of better images, best images, and additional images.

FIG. 12 is a diagram of a display screen showing preference information.

FIG. 13 is a schematic diagram showing accessibility to preference information by information terminals of registered persons.

### DESCRIPTION OF EMBODIMENTS

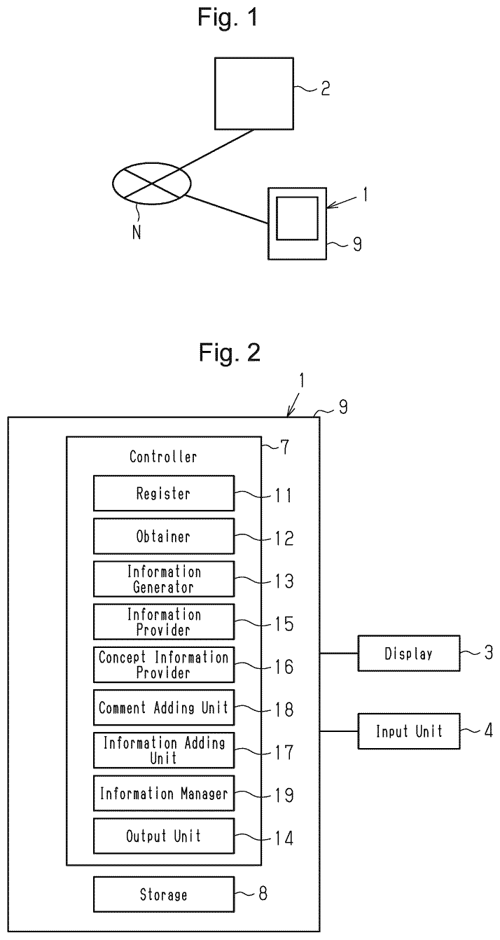

An interior communication assistance system 1 (hereafter, referred to as “assistance system 1”) will now be described with reference to FIGS. 1 to 13. In the present embodiment, the interior decor is also referred to as the “interior.” The assistance system 1 assists in planning the design of a building. The assistance system 1 includes an information terminal 9 such as a personal computer or a smartphone. The assistance system 1 includes hardware of the information terminal 9 and software installed in the information terminal 9.

As shown in FIG. 1, the assistance system 1 is configured to be connected to a display 3 that shows information. The assistance system 1 outputs information from the display 3, which is an external display. The assistance system 1 is configured to be connected to an input unit 4 into which information is input. The input unit 4 includes one of a keyboard, a touch pad, and a touch screen.

The assistance system 1 may include the display 3 showing information. The assistance system 1 may be connected to an external server 2 via a network N. In this case, the assistance system 1 obtains various types of information from the external server 2. The assistance system 1 may include the input unit 4.

The assistance system 1 includes a controller 7 and storage 8. The storage 8 stores multiple images P related to at least interior decor of a building. The storage 8 includes one of semiconductor memory such as RAM and ROM, a hard disk, magnetic tape, and an optical disc.

As shown in FIG. 2, the controller 7 includes a register 11, an obtainer 12, an information generator 13, and an output unit 14. The controller 7 includes one or more central processing units (CPU) or micro processing units (MPU), which operate based on programs. The controller 7 may include a circuit including a CPU or an MPU, a circuit including an application specific integrated circuit (ASIC), or a combination of the circuits. The controller 7 may include memory such as RAM and ROM. The memory stores programs that cause the CPU to execute processes.

The controller 7 may further include an information provider 15. The controller 7 may further include a concept information provider 16. The controller 7 may further include an information adding unit 17. The controller 7 may further include a comment adding unit 18. The controller 7 may further include an information manager 19.

Each component of the controller 7 such as the register 11, the obtainer 12, the information generator 13, the output unit 14, the information provider 15, the concept information provider 16, the information adding unit 17, the comment adding unit 18, and the information manager 19, may be implemented by a program or may be implemented as a circuit. In an example, the CPU executes a program corresponding to each component of the controller 7 so that the component performs its function.

### Register

The register 11 registers a person using the assistance system 1 as a registered person. The register 11 stores information related to the registered person in the storage 8 as registration information. The phrase “using the assistance system 1” includes answering a question provided from the assistance system 1.

The registration information includes at least registered person identification information, which identifies the registered person. The registered person identification information includes the name or a nickname of the registered person. The registration information may include gender, age, and relationship (e.g., child) with a main registered person. The registration information includes terminal identification information (e.g., e-mail address), which is used to identify the information terminal 9 of the registered person. The terminal identification information is associated with the registered person identification information.

The register 11 registers a number of registered persons as members of a group GP in accordance with group setting. More specifically, the register 11 adds group identification information to the registration information in accordance with the group setting. The group setting includes an input used for the setting of the group GP.

The register 11 registers a person who operates the assistance system 1 as an operator in accordance with operator setting. The operator setting includes an input used for the setting of the operator. The operator is a person who operates the assistance system 1 to determine requests from a registered person, or a customer. Examples of the operator include a designer, service staff associated with the registered person, a sales representative, and a designer associated with the design of a building.

### Image

An image P is an image of the interior decor. Multiple images P each have a different interior feature. The interior feature may be expressed by “sensitivity” of a person when viewing the image P. The images P may be stored in the storage 8 or the external server 2. In an example, thirty-six images P are stored in the storage 8. The thirty-six images P are categorized into six classes that greatly differ in sensitivity (interior feature). The sensitivity indicates images of the interior decor that are determined by the sensitivity of a person. Specifically, the six classes of sensitivity are Peaceful, Tender, Spirit, Cozy, Luxe, and Playful. Each sensitivity class includes six images P. The six images P in one class have the common sensitivity and differ in details of the sensitivity.

The Peaceful is a sensitivity image of an interior that conveys a serene atmosphere. A unifying low-contrast tone within the same color family, together with rounded silhouettes of furniture and accessories, characterizes the Peaceful.

The Tender is a sensitivity image of an interior that conveys a refreshing atmosphere. A combination of natural wood and white, providing a neat impression, with furniture having gentle curves that highlight the natural features of the wood, characterizes the Tender.

The Spirit is a sensitivity image of an interior that conveys a tense atmosphere.

Subdued natural materials, expressing spatial margin, together with furniture having crisp lines, characterize the Spirit.

The Cozy is a sensitivity image of an interior that conveys a warm atmosphere.

Colors highlighting the quality of the material, together with sturdy furniture, characterize the Cozy.

The Luxe is a sensitivity image of an interior that conveys a luxurious atmosphere. A combination of dark tones and glossy materials or luxurious furniture characterizes the Luxe.

The Playful is a sensitivity image of an interior that conveys an uplifting atmosphere. The background of a simple refined space, evoking an image of incorporating colors through furniture and accessories or enjoining the silhouettes, characterizes the Playful.

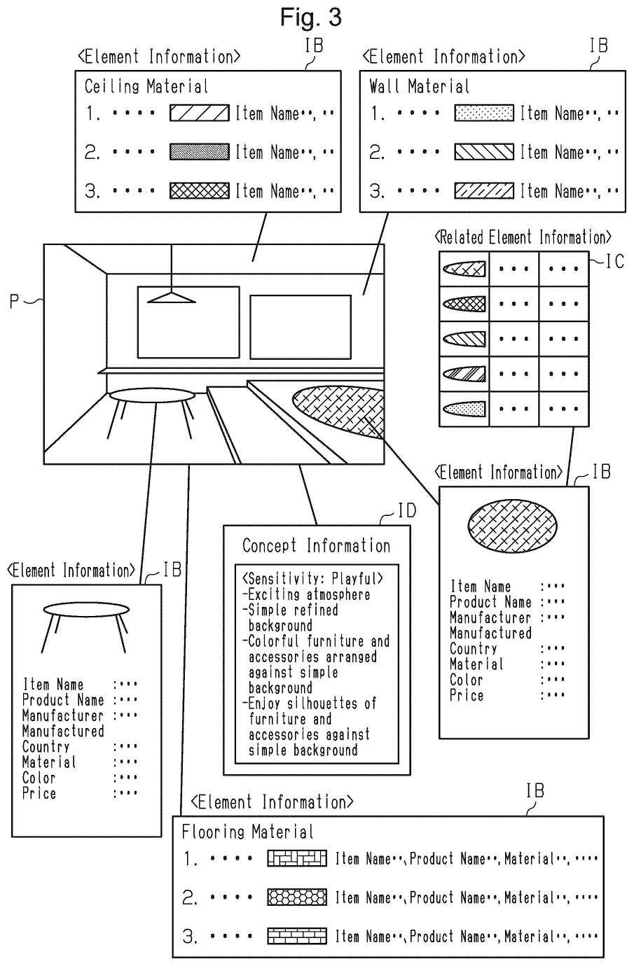

As shown in FIG. 3, each image P is configured to be associated with element information IB. FIG. 3 is a diagram showing the relationship of the image P and the element information IB. More specifically, each element in the image P is associated with element information IB related to the element. A surface element includes a surface element and an item element (refer to later description). The element includes building materials and items forming the interior decor. For example, when the image P includes wall covering, a flooring material, a ceiling material, and a table, the image P is associated with wall covering information, flooring material information, ceiling material information, and table information as the element information IB. The element information IB may be stored in the storage 8 or the external server 2.

The element information IB related to an element may be associated with related element information IC, which is information related to another element in the same type.

For example, when the image P includes a wall covering, a flooring material, a ceiling material, and a table, information may have the following structure. The wall covering information is associated with another wall covering information of the same type. The flooring material information is associated with another flooring material information of the same type. The ceiling material information is associated with another ceiling material information of the same type. The table information is associated with another table information of the same type. The phrase “same type” refers to the same sensitivity (interior feature), the same color tone, or the same type of material.

In addition, each image P may be configured to be associated with concept information ID, which describes the concept of the interior decor related to the image P. The concept information ID includes a description of the sensitivity of the interior decor (interior feature). The concept information ID may include an image of a person spending time there. The concept information ID may include a description of elements shown in the image P. In an example, when the sensitivity of the image P is “the Playful,” the concept information ID includes a description of “the Playful” and a description of a particular sensitivity of the image P. In addition, when the image P includes wall covering, a flooring material, a ceiling material, and a table as elements, the concept information ID may include a description and specification of the sensitivity of each of the wall covering, the flooring material, the ceiling material, and the table.

### Obtainer

The obtainer 12 is configured to obtain information on a preference of the registered person from questions. Specifically, the obtainer 12 obtains an answer to a question as answer information. More specifically, when the image P and a question about the image P are shown on the display 3, the obtainer 12 obtains an answer to the question from the registered person as the answer information. The question includes a first question and a second question.

An example of the present embodiment will be described below. In the present embodiment, the question includes a third question in addition to the first question and the second question.

### 1. First Question

When the image P and the first question about the image P are shown on the display 3, the obtainer 12 obtains a first answer to the first question from the registered person as the answer information.

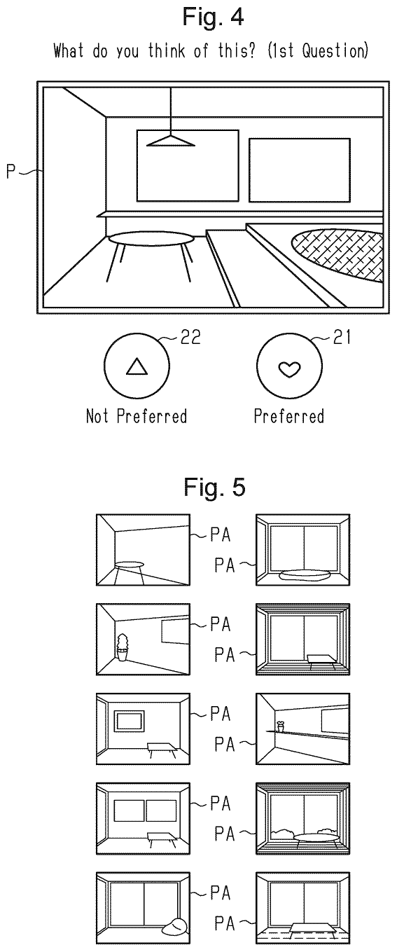

FIG. 4 shows a display screen of the display 3. FIG. 4 shows an example of the first question. The first question asks the registered person to select whether the image P is preferred. The obtainer 12 shows the image P on the display 3 and also shows a first button 21 for selection of “preferred” and a second button 22 for selection of “not preferred.” When one of the first button 21 and the second button 22 is selected, the obtainer 12 obtains the selection as first answer information. The obtainer 12 sends the first answer information of each image P to the information generator 13.

The obtainer 12 performs the same process on all of the thirty-six images P and obtains the first answer information about the first question. This specifies images P that is preferred by the registered person (hereafter, referred to as the better images PA).

As shown in FIG. 5, when the registered person selects two or more better images PA, the output unit 14 shows the images PA as a list on the display 3. The list of the better images PA may be shown when a list presentation instruction is input to the assistance system 1.

### 2. Third Question

Following the process corresponding to the first question, the obtainer 12 executes a process corresponding to the third question. The third question asks the registered person to select a predetermined number of images P that are more preferred among the better images PA, which are selected as preferred in the first question, as the best images PB.

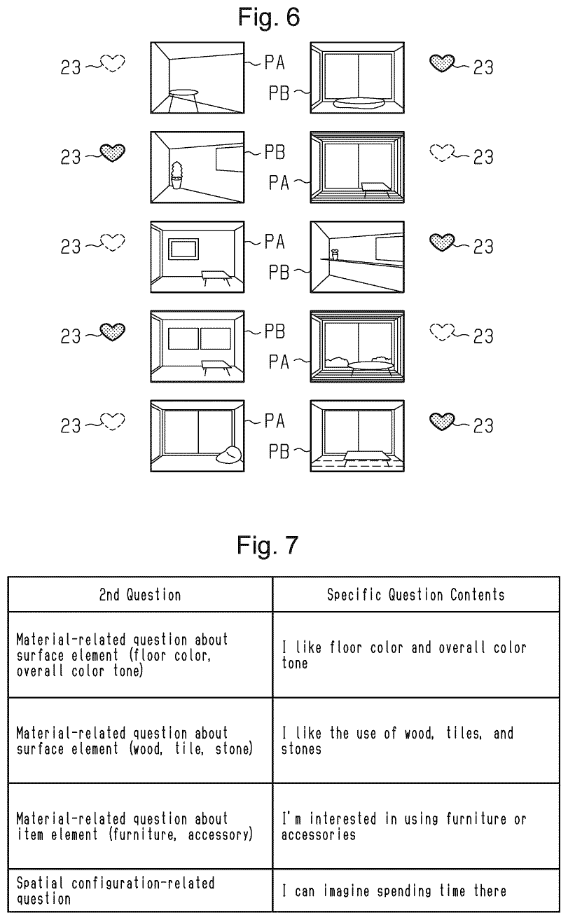

FIG. 6 shows a display screen of the display 3. FIG. 6 shows an example of the third question. In FIG. 6, a description such as “Select five more preferred images P” may be shown. FIG. 6 shows an example of a case in which the predetermined number is five.

The obtainer 12 shows, on the display 3, the list of the better images PA and third buttons 23 located adjacent to the images P for selection of “more preferred.” When a third button 23 is selected, the obtainer 12 obtains selection of the image P as third answer information. The obtainer 12 sends the third answer information of each image P to the information generator 13.

The obtainer 12 performs the same process on all of the better images PA and obtains the third answer information about the third question. As a result, among the images P preferred by the registered person, more preferred images P (hereafter, the best images PB) are specified.

### 3. Second Question

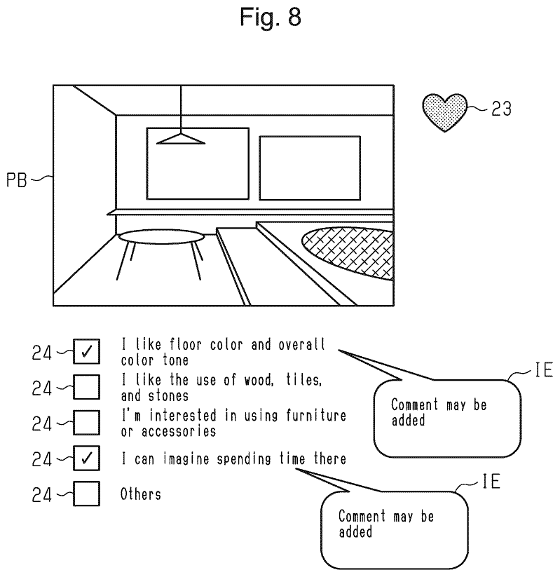

Referring to FIGS. 7 and 8, the second question will be described. FIG. 8 shows a display screen of the display 3. FIG. 8 shows an example of the second question. In FIG. 8, an instruction such as “Please check applicable question contents” may be shown.

The second question includes at least one of a material-related question and a spatial configuration-related question. The second question asks about the best images PB.

The material-related question asks the registered person to select whether a particular element of the interior decor in the image P is preferred. The particular element includes a surface element and an item element of an item forming the interior decor. The surface element forms a surface of the interior decor. The surface element includes at least one of a floor of the interior decor, a wall of the interior decor, and a ceiling of the interior decor. The item element is an object forming the interior decor and configured to be arranged on the floor, the wall, or a table. The item element includes at least one of lighting of the interior decor and an interior accessory forming the interior decor. Examples of the interior accessory include a vase, a clock, a painting, an ornament, a plant, and a household appliance.

The material-related question includes a question asking whether the surface element is preferred (hereafter, may be referred to as Question A) and a question asking whether the item element is preferred (hereafter, may be referred to as Question B).

In an example, the question asking whether the surface element is preferred (i.e., Question A) is “whether the registered person likes the floor color and the overall color tone.” This obtains the preference about the color tones of the floor and wall of the interior decor. Another example of Question A is “whether the registered person “likes the use of wood, tiles, and stones.” This obtains information on whether the way the wood, tiles, and stones are used in the floor and wall of the interior decor is preferred.

In an example, the question asking whether the item element is preferred (i.e., Question B) is “whether the registered person is interested in using the furniture or accessories.” This obtains the preference of items. As described above, a question asking without specifying items reduces the number of questions. The assistance system 1 is configured to allow a detail of preference to be input to a comment section, which will be described later.

The spatial configuration-related question asks the registered person to select whether the interior decor in the image P or the space in which the interior decor is represented is preferred. This question is aimed to obtain a preferred interior feature of the interior decor (specifically, sensitivity of the interior) from the spatial configuration-related question.

In an example, the question asking whether the interior decor in the image P or the space in which the interior decor is represented is preferred is “whether the registered person can imagine spending time there.” The imagination of spending time infers presence of preference of the registered person. This question obtains information of whether the interior feature of the image P (specifically, sensitivity of the interior in the image P) is preferred.

The obtainer 12 obtains answers to the second question about the best images PB, which are selected as preferred in the third question, as second answer information. The obtainer 12 obtains second answer information on each best image PB.

Specifically, the obtainer 12 shows one of the best images PB on the display 3 and one or more contents of the second question near the best image PB (refer to FIG. 8). The obtainer 12 shows a check button 24 for each second question on the display 3. When the check button 24 corresponding to any content of the second question is selected, the obtainer 12 obtains the selection of the check button 24 for the content as second answer information. The obtainer 12 associates the second answer information with the best image PB.

The obtainer 12 performs the same process on all of the best images PB and obtains the second answer information on the second question. Thus, information on a preferred part of the best images PB is obtained.

The obtainer 12 may obtain second answer information on the better image PA instead of on the best images PB. More specifically, the obtainer 12 may obtain answers to the second question about the better images PA, which are selected as preferred in the first question, as second answer information. The obtainer 12 obtains the second answer information on each better image PA.

### Information Generator

The information generator 13 generates preference information IA. The preference information IA is about a preference of the registered person regarding the design of interior decor. The information generator 13 generates the preference information IA in which the preference of the registered person is organized based on the answer information. The information generator 13 generates preference information IA for each registered person.

More specifically, the preference information IA includes the registered person and the better images PA, which are selected as preferred in the first question. In the preference information IA, the registration information on the registered person is associated with the best images PB and the second answer information. In the preference information IA, the registration information on the registered person may be associated with the better images PA and the second answer information.

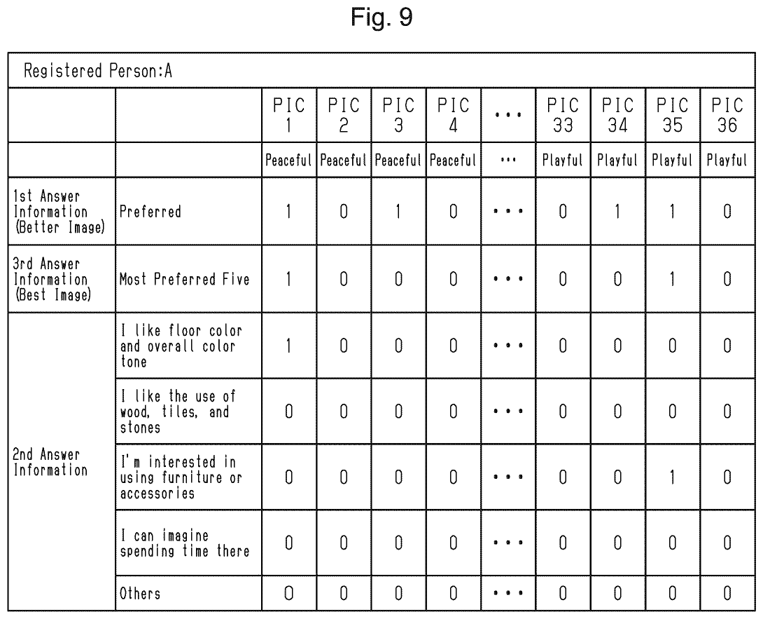

As shown in FIG. 9, the information generator 13 generates the preference information IA in a table format. In FIG. 9, the thirty-six images P are referred to as PIC1 to PIC36. The interior feature (specifically, sensitivity of the interior) for each image P is shown in the section under the row indicating the image P (PIC1 to PIC36). In the preference information IA, for each of the thirty-six images P, information of whether the image P is preferred and thus is a better image PA (first answer information), information of whether the image P is more preferred and thus is a best image PB (third answer information), and the second answer information on the second question are associated with each other. The preference information IA facilitates determination of the interior decor (or the space in which the interior decor is represented) having an interior feature (specifically, sensitivity of the interior) that is selected as preferred, preferred color tones of the wall or the floor, and a preferred item. The data format of the information generator 13 is not limited. The preference information IA may be in an array format.

### Comment Adding Unit

The comment adding unit 18 adds a comment of the registered person to the preference information IA on the registered person.

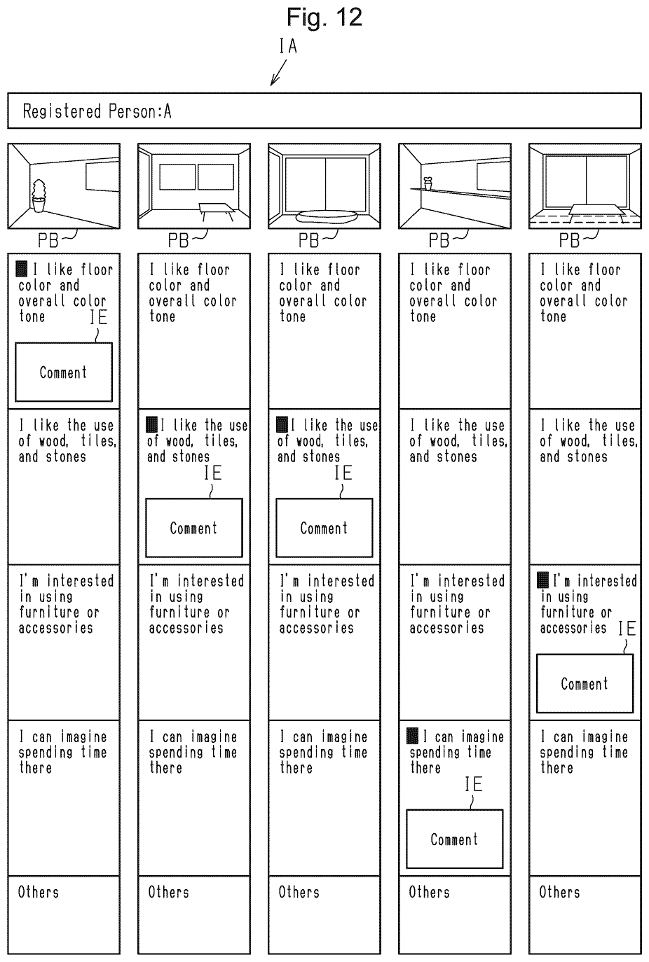

The comment adding unit 18 adds comment information IE, which is a comment entered by the registered person on a positively answered content of the second question, to the preference information IA so that the comment information IE is associated with the content (positively answered content) in the preference information IA (refer to FIG. 12). The positive answer refers to selection of the check button 24.

A comment is entered as text. For example, when the registered person selects the check button 24 for “I'm interested in using the furniture or accessories” in the second question, a comment section appears on the display screen, and a comment may be entered in the comment section. For example, “I want to use the vase.”, “I like the table”, or “The cushion is nice.” may be entered to the comment section. The comments allow the designer to deeply analyze the preference of the registered person.

### Information Provider

The information provider 15 provides information related to an element included in the image P. The element is an element of the interior decor. The element related to provision of information includes the particular element (refer to description above) related to the questions. The element may include an element other than the particular element.

The information provider 15 provides information mainly to the designer. The information manager 19, which will be described later, controls to allow only the designer, or the operator, to access the information provided to the information provider 15.

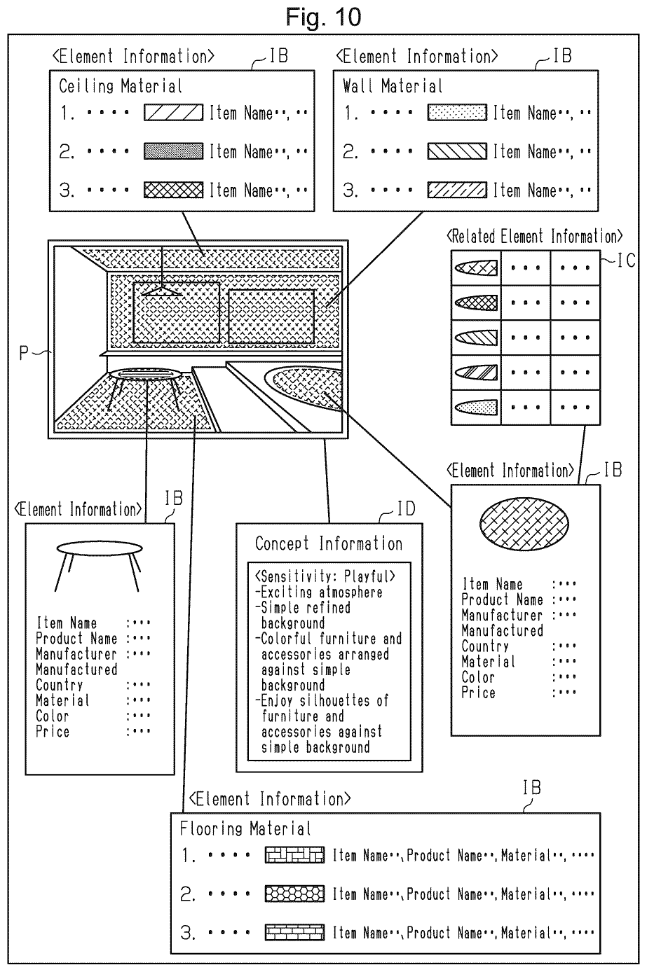

As shown in FIG. 10, when the image P is shown on the display 3, the information provider 15 forms a link to the element information IB of each element included in the image P on the display 3 so that the element information IB of the element is shown in response to selection of a predetermined position on the display screen. In FIG. 10, the hatching indicates locations provided with links.

More specifically, the link to the element information IB of each element is invisibly provided to the display screen of the display 3 where the element is shown. Thus, when the designer selects (e.g., touches) a portion of an element in the screen, the element information IB of the element is shown on the screen.

In addition, when the image P is shown on the display 3, the information provider 15 may form a link to the related element information IC on the display 3 so that the related element information IC is shown in response to selection of a predetermined position of the display screen.

### Concept Information Provider

The concept information provider 16 provides the concept of the interior decor included in the image P. When the image P is shown on the display 3, the concept information provider 16 forms a link to the concept information ID on the display 3 so that the concept information ID is shown in response to selection of a predetermined position of the display screen (refer to FIG. 10). The concept information ID is associated with the image P as described above.

### Information Adding Unit

The information adding unit 17 adds information to the preference information IA on the registered person. The information adding unit 17 adds an additional image PX, which is provided by the registered person, to the preference information IA as a piece of the preference information IA on the registered person. More specifically, the information adding unit 17 executes a process of showing an entry screen for entering an image P on the display 3 and a process of storing an image P that is entered through the entry screen in the storage 8 as the additional image PX of the registered person.

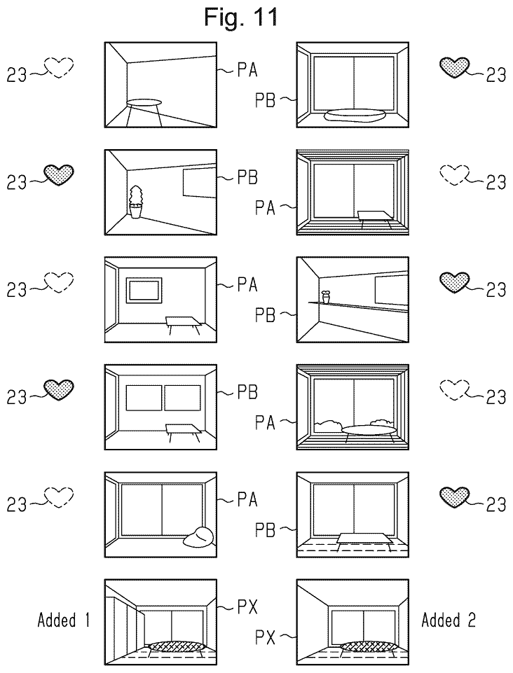

As shown in FIG. 11, the information adding unit 17 shows a list of the additional images PX together with the best images PB when the list presentation instruction is input to the assistance system 1. The additional images PX are shown so as to be distinguished from the remaining images P. In an example, the word “Added” is shown near the additional images PX.

### Output Unit

The output unit 14 outputs the preference information IA, which will be described later, to the display 3 so that the display 3 shows the preference information IA.

An example of the preference information IA that is output from the output unit 14 to the display 3 will be described with reference to FIG. 12. FIG. 12 shows an example of the display screen showing the preference information IA. The preference information IA including the images P and a list of answers to questions are shown on the display screen of the display 3. The preference information IA includes the registration information on the registered person who has answered the questions, a predetermined number of (e.g., five) best images PB, and the answer information on each best image PB (the first answer information, the second answer information, and the third answer information). As shown in FIG. 12, the preference information IA is shown in a table format.

### Information Manager

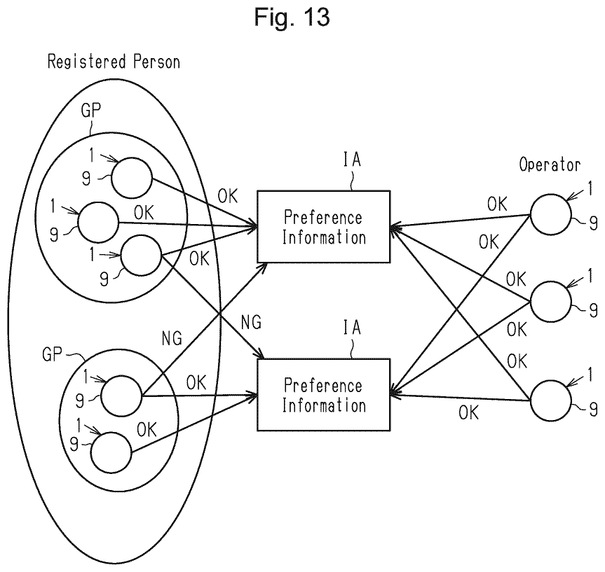

The information manager 19 will now be described with reference to FIG. 13. FIG. 13 is a schematic diagram showing accessibility to the preference information IA by the information terminal 9 of the registered person.

The information manager 19 manages information obtained by the obtainer 12. The information manager 19 allows the information terminal 9 of a registered person who is a member of the group GP to access the preference information IA so that the preference information IA is shared by only the members in the group GP. The information manager 19 restricts the access to the preference information IA by the information terminal 9 of a registered person who is outside the group GP. The information manager 19 allows the operator to access registered person information and the preference information IA.

The first operation of the present embodiment will be described below.

In this technique, when the image P and a question about the image P are shown on the display 3, an answer to the question is obtained as answer information. More specifically, the questions are provided for the image P in advance, and the registered person answers the questions. This allows for analysis of the preference of the registered person about the interior decor. Then, preference information IA on the registered person is formed from the answers of the registered person (e.g., customer). Thus, information related to the building material and items may be provided in accordance with the preference of the registered person about the interior decor.

The second operation of the present embodiment will be described below.

Preference of interior decor greatly varies among individuals and thus is difficult to accurately determine only from the interior feature (more specifically, sensitivity of the interior) of the interior decor as a whole. In an example, a person may prefer the interior feature of the Playful as a whole. However, the person may prefer the interior feature of the Cozy in terms of items (item elements).

The interior feature (more specifically, sensitivity of the interior) is generally determined by the ceiling material (i.e., the surface element). However, the detail of the interior feature may be adjusted by items. The interior feature may greatly change depending on selection of an item. Also, one or more items may greatly change the interior feature.

The person may have different impressions of an item between when looking at the item as part of the interior decor and when looking at the item only. For example, the person may not have much interest in a table having the image of the Cozy by itself. However, when the table having the image of the Cozy is arranged in a Playful indoor space, the person may think that the combination of the table and the space is “fine.” As described above, it is difficult to accurately determine the preference of the interior decor of a person based on only the interior feature of the interior decor (more specifically, sensitivity of the interior) as a whole. That is, it is difficult to accurately determine the preference of the person simply by obtaining a preference of each image P of the interior decor.

In this technique, when the image P and a second question about the image P are shown on the display 3, an answer to the question is obtained as answer information. As described above, the second question includes at least one of the material-related question and the spatial configuration-related question. This allows for detailed analysis of preference of the registered person regarding the interior decor. For example, the analysis may be conducted to determine whether the registered person likes the interior feature (more specifically, sensitivity of the interior) of the overall interior decor shown in the image P, whether the registered person particularly likes one of the materials (the surface element and the item element), or whether the registered person likes the combination of any of the materials and the interior. Thus, the assistance system 1 assists in accurately determining the preference of the registered person (e.g., customer). In addition, the assistance system 1 facilitates determination of the tendency of the preference of the registered person, thereby facilitating communication between the registered person (e.g., customer) and the operator (e.g., designer). This leads to a proposal of a design that conforms to the preference of the registered person.

The present embodiment has the following advantages.
(1) In the assistance system 1, when the image P and a question about the image P are shown on the display 3, the obtainer 12 obtains an answer to the question from the registered person as answer information. The information generator 13 generates the preference information IA in which the preference of the registered person is organized based on the answer information. This configuration assists the designer in accurately determining the preference of the registered person (e.g., customer).
(2) When the image P and the first question about the image P are shown on the display 3, the obtainer 12 obtains the first answer to the first question from the registered person as answer information. The first question asks the registered person to select whether the image P is preferred. The information generator 13 generates preference information IA including the registered person and the better image PA, which is selected as preferred in the first question. This configuration allows for determination of the design of the interior decor that is preferred by the registered person.
(3) The obtainer 12 obtains answers to the second question about the better image PA, which is selected as preferred in the first question, as second answer information. The second question includes at least one of the material-related question and the spatial configuration-related question. The information generator 13 generates preference information IA in which the registered person is associated with the better image PA and the second answer information. This configuration allows for determination of the design of the interior decor preferred by the registered person or the interior space (space expressed by the interior decor) preferred by the registered person. Also, this configuration allows for determination of which part of the preferred interior decor is preferred.
(4) The obtainer 12 obtains answers to the second question about the best image PB, which is selected as preferred in the third question, as second answer information. The third question asks the registered person to select a predetermined number of images P that are more preferred among the better images PA, which are selected as preferred in the first question, as the best images PB. The second question includes at least one of the material-related question and the spatial configuration-related question. The information generator 13 generates preference information IA in which the registered person is associated with the best images PB and the second answer information. This configuration allows for narrowing down of the design of the interior decor preferred by the registered person or the interior space (space expressed by the interior decor) preferred by the registered person. Also, this configuration allows for determination of which part of the preferred interior decor is preferred.
(5) In the assistance system 1, when the registered person positively answers a content of the second question and enters a comment on the content, the comment adding unit 18 adds the comment to the preference information IA so that the comment is associated with the positively answered content. This configuration allows for determination of the comment on the part that is preferred by the registered person. This allows the designer to analyze the preference of the registered person (e.g., customer).
(6) The material-related question, which is included in the second question, includes a question asking whether the surface element is preferred, and a question asking whether the item element is preferred. In this configuration, the second question is divided into a question about the surface element and a question about the item element. This allows for determination or inference of whether the surface element is preferred, whether the item element is preferred, whether both the surface element and the item element are preferred, or whether a combination of the surface element and the item element is preferred in the preferred interior decor.
(7) In the assistance system 1, when the image P is shown on the display 3, the information provider 15 forms a link to the element information IB of each element included in the image P on the display 3 so that the element information IB of the element is shown when selected. With this configuration, information about the building materials of the interior decor preferred by the registered person is obtained in detail.
(8) In the assistance system 1, when the image P is shown on the display 3, the information provider 15 forms a link to the related element information IC on the display 3 so that the related element information IC is shown when selected. With this configuration, various building materials that may be close to the preference of the registered person may be proposed based on the interior decor preferred by the registered person.
(9) In the assistance system 1, when the image P is shown on the display 3, the concept information provider 16 forms a link to the concept information ID on the display 3 so that the concept information ID of the interior decor in the image P is shown when selected. This configuration allows for determination of the concept of the interior decor that is preferred by the registered person.
(10) In the assistance system 1, the information adding unit 17 adds an additional image PX, which is provided by the registered person, to the preference information IA as a piece of the preference information IA on the registered person. With this configuration, the additional image PX allows for deep understanding of the preference of the registered person.
(11) In the assistance system 1, the information manager 19 allows the information terminal 9 of a registered person who is a member of the group GP to access the preference information IA so that the preference information IA is shared by only the members in the group GP. The information manager 19 restricts the access to the preference information IA by the information terminal 9 of a registered person who is outside the group GP. With this configuration, the preference of each member in the group GP is shared. For example, when all members in a family decide interior decor of the building, the members may share their preferences. Thus, the proposal of the interior decor is readily finalized.
(12) In the assistance system 1, the information manager 19 allows an operator to access the registered person information and the preference information IA. This configuration allows all of the registered operators (e.g., designer, architect) to share the preference of the registered person. When the interior decor is designed by multiple operators, the operators can share the information to smoothly design the interior decor.

### MODIFIED EXAMPLES

The above embodiments exemplify, without any intention to limit, applicable forms of the assistance system 1. The assistance system 1 is applicable to forms different from the examples described in the above embodiment. For example, the structures of the embodiment may be replaced, changed, or omitted in part or include additional elements. Modified examples of the embodiment will be described below.

The assistance system 1 may include a program. The interior communication assistance program assists in planning the design of a building. The interior communication assistance program (hereafter, “assistance program”) includes the following steps. The computer described below may be a personal computer, a smartphone, or a server. The first step causes the computer to store multiple images P of at least interior decor of a building. The second step causes the computer to register a person who uses the assistance program as a registered person and to store information related to the registered person in the storage 8 as registration information. The third step causes the computer, when an image P and a question about the image P are shown on the display 3, to obtain an answer to the question from the registered person as answer information. The fourth step causes the computer to generate preference information IA in which the preference of the registered person is organized based on the answer information. The fifth step causes the computer to show the preference information IA on the display 3. This configuration assists the designer in accurately determining the preference of the registered person (e.g., customer). The order of executing the first to fifth steps is not limited.

The assistance program may further include the following steps. The sixth step replaces the third step. The sixth step causes the computer, when an image P and a first question about the image P are shown on the display 3, to obtain a first answer to the first question from the registered person as answer information. The seventh step causes the computer to obtain an answer to a second question about a better image PA, which is selected as preferred in the first question, as second answer information. The eighth step causes the computer to generate preference information IA in which the registered person is associated with the better image PA and the second answer information. The sixth step causes the computer to show the preference information IA on the display 3. The first question and the second question are the same as those in the embodiment.

Technical aspects disclosed in the specification are disclosed below.

### Clause 1

The present disclosure according to clause 1 is an interior communication assistance system that assists in design planning of a building and includes the following.

The interior communication assistance system includes a controller and storage. The storage stores multiple images of at least an interior decor of the building.

The controller includes a register configured to register a person who uses the interior communication assistance system as a registered person and store information related to the registered person in the storage as registration information, an obtainer configured, when the images and a question about the images are shown on a display, to obtain an answer to the question from the registered person as answer information, an information generator configured to generate preference information in which preference of the registered person is organized based on the answer information, and an output unit configured to show the preference information on the display.

### Clause 2

The present discloser according to clause 2 is the interior communication assistance system according to clause 1 and includes the following. The images, each of which includes an image of an interior decor, differ from each other in interior feature. The question includes a first question that asks the registered person to select whether the images are preferred. When the images and the first question about the images are shown on the display, the obtainer obtains an answer to the first question from the registered person as first answer information. The information generator generates the preference information including the registration information and a better image selected as preferred in the first question.

### Clause 3

The present discloser according to clause 3 is the interior communication assistance system according to clause 2 and includes the following.

The question includes a second question including at least one of a material-related question and a spatial configuration-related question, the material-related question asking the registered person to select whether a particular element of the interior decor in the images is preferred, and the spatial configuration-related question asking the registered person to select whether the interior decor in the images or a space in which the interior decor is represented is preferred.

The obtainer obtains an answer to the second question about the better image, which is selected as preferred in the first question, as second answer information.

The information generator generates the preference information in which the registration information is associated with the better image and the second answer information.

### Clause 4

The present discloser according to clause 4 is the interior communication assistance system according to clause 2 and includes the following.

The question includes a second question including at least one of a material-related question and a spatial configuration-related question, the material-related question asking the registered person to select whether a particular element of the interior decor in the images is preferred, and the spatial configuration-related question asking the registered person to select whether the interior decor in the images or a space in which the interior decor is represented is preferred, and a third question asking the registered person to select a predetermined number of images from the better image, which is selected as preferred in the first question, as a best image. The best image is more preferred among the better image.

The obtainer obtains an answer to the second question about the best image, which is selected as more preferred in the third question, as second answer information.

The information generator generates the preference information in which the registration information is associated with the best image and the second answer information.

### Clause 5

The present discloser according to clause 5 is the interior communication assistance system according to clause 4 and includes the following.

The controller further includes a comment adding unit that adds a comment of the registered person to the preference information on the registered person.

The comment adding unit adds a comment entered by the registered person on a question content that is positively answered in the second question to the preference information so that the comment is associated with the question content.

### Clause 6

The present discloser according to clause 6 is the interior communication assistance system according to any one of clauses 3 to 5 and includes the following.

The particular element includes a surface element that forms a surface of an interior decor and an item element related to an item forming the interior decor.

The surface element includes at least one of a floor of the interior decor, a wall of the interior decor, and a ceiling of the interior decor.

The item element includes at least one of lighting of the interior decor and an interior accessory forming the interior decor.

The material-related question includes a question asking whether the surface element is preferred and a question asking whether the item element is preferred.

### Clause 7

The present discloser according to clause 7 is the interior communication assistance system according to clause 1 and includes the following.

The controller further includes an information provider configured to provide information related to an element included in the image.

In the images, each image is configured so that the element included in the image is associated with element information related to the element.

When the image is shown on the display, the information provider forms a link to the element information of the element included in the image on the display so that the element information of the element is shown when selected.

### Clause 8

The present discloser according to clause 8 is the interior communication assistance system according to clause 7 and includes the following.

The element information related to the element is configured to be associated with related element information that is in same type as the element. When the image is shown on the display, the information provider forms a link to the related element information on the display so that the related element information is shown when selected.

### Clause 9

The present discloser according to clause 9 is the interior communication assistance system according to clause 1 and includes the following.

In the images, each image is configured to be associated with concept information describing concept of an interior decor related to the image. The controller further includes a concept information provider configured to provide a concept of an interior decor included in the image. When the image is shown on the display, the concept information provider forms a link to the concept information on the display so that the concept information is shown when selected.

### Clause 10

The present discloser according to clause 10 is the interior communication assistance system according to clause 1 and includes the following.

The controller further includes an information adding unit configured to add information to the preference information on the registered person. The information adding unit adds an additional image provided by the registered person to the preference information as a piece of the preference information on the registered person.

### Clause 11

The present discloser according to clause 11 is the interior communication assistance system according to clause 1 and includes the following.

The controller further includes an information manager configured to manage information obtained by the obtainer. The registered person includes multiple registered persons. The register registers the registered persons as members of a group in accordance with group setting. The information generator generates the preference information for each of the registered persons. The information manager allows an information terminal of the registered person who is a member in the group to access the preference information and restricts access to the preference information by an information terminal of the registered person outside the group so that the preference information is shared by only the members of the group.

### Clause 12

The present discloser according to clause 12 is the interior communication assistance system according to clause 11 and includes the following. The register registers a person who operates the interior communication assistance system in accordance with operator setting. The information manager allows the operator to access the registered person information and the preference information.

### Clause 13

The present discloser according to clause 13 is an interior communication assistance program that assists in design planning of a building and includes the following.

The interior communication assistance program includes a step of causing a computer to store multiple images of at least an interior decor of the building, a step of causing the computer to register a person who uses the interior communication assistance program as a registered person and store information related to the registered person in storage as registration information, a step of causing the computer, when the images and a question about the images are shown on a display, to obtain an answer to the question from the registered person as answer information, a step of causing the computer to generate preference information in which preference of the registered person is organized based on the answer information, and a step of causing the computer to show the preference information on the display. This configuration assists the designer in accurately determining the preference of the registered person (e.g., customer).

### REFERENCE SIGNS LIST

GP) group, IA) preference information, IB) element information, IC) related element information, ID) concept information, P) image, PA) better image, PB) best image, PX) additional image, 1) interior communication assistance system, 3) display, 7) controller, 8) storage, 11) register, 12) obtainer, 13) information generator, 14) output unit, 15) information provider, 16) concept information provider, 17) information adding unit, 18) comment adding unit, 19) information manager

1. An interior communication assistance system assisting in design planning of a building, the interior communication assistance system, comprising:
a controller; and
storage, wherein
the storage stores multiple images of at least an interior decor of the building,
the controller includes:
a register configured to register a person who uses the interior communication assistance system as a registered person and store information related to the registered person in the storage as registration information;
an obtainer configured, when the images and a question about the images are shown on a display, to obtain an answer to the question from the registered person as answer information;
an information generator configured to generate preference information in which preference of the registered person is organized based on the answer information; and
an output unit configured to show the preference information on the display, wherein
the images, each including an image of an interior decor, differ from each other in interior feature,
the question includes:
a first question that asks the registered person to select whether the images are preferred; and
a second question including at least one of a material-related question and a spatial configuration-related question, the material-related question asking the registered person to select whether a particular element of the interior decor in the images is preferred, and the spatial configuration-related question asking the registered person to select whether the interior decor in the images or a space in which the interior decor is represented is preferred,
when the images and the first question about the images are shown on the display, the obtainer obtains an answer to the first question from the registered person as first answer information,
the obtainer obtains an answer to the second question about a better image, which is selected as preferred in the first question, as second answer information, and the information generator generates:
the preference information including the registration information and the better image selected as preferred in the first question; and
the preference information in which the registration information is associated with the better image and the second answer information.

2. (canceled)

3. (canceled)

4. (canceled)

5. (canceled)

6. The interior communication assistance system according to claim 1, wherein
the particular element includes a surface element that forms a surface of an interior decor and an item element related to an item forming the interior decor,
the surface element includes at least one of a floor of the interior decor, a wall of the interior decor, and a ceiling of the interior decor,
the item element includes at least one of lighting of the interior decor and an interior accessory forming the interior decor, and
the material-related question includes a question asking whether the surface element is preferred and a question asking whether the item element is preferred.

7. The interior communication assistance system according to claim 1, wherein
the controller further includes an information provider configured to provide information related to an element included in the image,
in the images, each image is configured so that the element included in the image is associated with element information related to the element, and
when the image is shown on the display, the information provider forms a link to the element information of the element included in the image on the display so that the element information of the element is shown when selected.

8. The interior communication assistance system according to claim 7, wherein
the element information related to the element is configured to be associated with related element information that is in same type as the element, and
when the image is shown on the display, the information provider forms a link to the related element information on the display so that the related element information is shown when selected.

9. The interior communication assistance system according to claim 1, wherein
in the images, each image is configured to be associated with concept information describing concept of an interior decor related to the image,
the controller further includes a concept information provider configured to provide a concept of an interior decor included in the image,
when the image is shown on the display, the concept information provider forms a link to the concept information on the display so that the concept information is shown when selected.

10. The interior communication assistance system according to claim 1, wherein
the controller further includes an information adding unit configured to add information to the preference information on the registered person, and
the information adding unit adds an additional image provided by the registered person to the preference information as a piece of the preference information on the registered person.

11. The interior communication assistance system according to claim 1, wherein
the controller further includes an information manager configured to manage information obtained by the obtainer,
the registered person includes multiple registered persons,
the register registers the registered persons as members of a group in accordance with group setting,
the information generator generates the preference information for each of the registered persons,
the information manager allows an information terminal of the registered person who is a member in the group to access the preference information and restricts access to the preference information by an information terminal of the registered person outside the group so that the preference information is shared by only the members of the group.

12. The interior communication assistance system according to claim 11, wherein
the register registers a person who operates the interior communication assistance system in accordance with operator setting, and
the information manager allows the operator to access the registered person information and the preference information.

13. An interior communication assistance program assisting in design planning of a building, the interior communication assistance program, comprising:
causing a computer to store multiple images of at least an interior decor of the building;
causing the computer to register a person who uses the interior communication assistance program as a registered person and store information related to the registered person in storage as registration information;
causing the computer, when the images and a question about the images are shown on a display, to obtain an answer to the question from the registered person as answer information;
causing the computer to generate preference information in which preference of the registered person is organized based on the answer information; and
causing the computer to show the preference information on the display, wherein
the images, each including an image of an interior decor, differ from each other in interior feature,
the question includes:
a first question that asks the registered person to select whether the images are preferred; and
a second question including at least one of a material-related question and a spatial configuration-related question, the material-related question asking the registered person to select whether a particular element of the interior decor in the images is preferred, and the spatial configuration-related question asking the registered person to select whether the interior decor in the images or a space in which the interior decor is represented is preferred,
when the images and the first question about the images are shown on the display, the interior communication assistance program causes the computer to obtain an answer to the first question from the registered person as first answer information,
the interior communication assistance program causes the computer to obtain an answer to the second question about a better image, which is selected as preferred in the first question, as second answer information, and
the interior communication assistance program causes the computer to generate:
the preference information including the registration information and the better image selected as preferred in the first question, and
the preference information in which the registration information is associated with the better image and the second answer information.

14. An interior communication assistance system assisting in design planning of a building, the interior communication assistance system, comprising:
a controller; and
storage, wherein
the storage stores multiple images of at least an interior decor of the building, the controller includes:
a register configured to register a person who uses the interior communication assistance system as a registered person and store information related to the registered person in the storage as registration information;
an obtainer configured, when the images and a question about the images are shown on a display, to obtain an answer to the question from the registered person as answer information;
an information generator configured to generate preference information in which preference of the registered person is organized based on the answer information; and
an output unit configured to show the preference information on the display, wherein the images, each including an image of an interior decor, differ from each other in interior feature,
the question includes:
a first question that asks the registered person to select whether the images are preferred;
a second question including at least one of a material-related question and a spatial configuration-related question, the material-related question asking the registered person to select whether a particular element of the interior decor in the images is preferred, and the spatial configuration-related question asking the registered person to select whether the interior decor in the images or a space in which the interior decor is represented is preferred; and
a third question asking the registered person to select a predetermined number of images from a better image, which is selected as preferred in the first question, as a best image, the best image being more preferred among the better image,
when the images and the first question about the images are shown on the display, the obtainer obtains an answer to the first question from the registered person as first answer information,
the obtainer obtains an answer to the second question about the best image, which is selected as more preferred in the third question, as second answer information, and
the information generator generates:
the preference information including the registration information and the better image selected as preferred in the first question; and
the preference information in which the registration information is associated with the best image and the second answer information.

15. The interior communication assistance system according to claim 14, wherein
the controller further includes a comment adding unit that adds a comment of the registered person to the preference information on the registered person, and
the comment adding unit adds a comment entered by the registered person on a question content that is positively answered in the second question to the preference information so that the comment is associated with the question content.

16. The interior communication assistance system according to claim 14, wherein
the particular element includes a surface element that forms a surface of an interior decor and an item element related to an item forming the interior decor,
the surface element includes at least one of a floor of the interior decor, a wall of the interior decor, and a ceiling of the interior decor,
the item element includes at least one of lighting of the interior decor and an interior accessory forming the interior decor, and
the material-related question includes a question asking whether the surface element is preferred and a question asking whether the item element is preferred.

17. The interior communication assistance system according to claim 14, wherein
the controller further includes an information provider configured to provide information related to an element included in the image,
in the images, each image is configured so that the element included in the image is associated with element information related to the element, and
when the image is shown on the display, the information provider forms a link to the element information of the element included in the image on the display so that the element information of the element is shown when selected.

18. The interior communication assistance system according to claim 17, wherein
the element information related to the element is configured to be associated with related element information that is in same type as the element, and
when the image is shown on the display, the information provider forms a link to the related element information on the display so that the related element information is shown when selected.

19. The interior communication assistance system according to claim 14, wherein
in the images, each image is configured to be associated with concept information describing concept of an interior decor related to the image,
the controller further includes a concept information provider configured to provide a concept of an interior decor included in the image,
when the image is shown on the display, the concept information provider forms a link to the concept information on the display so that the concept information is shown when selected.

20. The interior communication assistance system according to claim 14, wherein
the controller further includes an information adding unit configured to add information to the preference information on the registered person, and
the information adding unit adds an additional image provided by the registered person to the preference information as a piece of the preference information on the registered person.

21. The interior communication assistance system according to claim 14, wherein
the controller further includes an information manager configured to manage information obtained by the obtainer,
the registered person includes multiple registered persons,
the register registers the registered persons as members of a group in accordance with group setting,
the information generator generates the preference information for each of the registered persons,
the information manager allows an information terminal of the registered person who is a member in the group to access the preference information and restricts access to the preference information by an information terminal of the registered person outside the group so that the preference information is shared by only the members of the group.

22. The interior communication assistance system according to claim 21, wherein
the register registers a person who operates the interior communication assistance system in accordance with operator setting, and
the information manager allows the operator to access the registered person information and the preference information.
